(19) United States
(12) Patent Application Publication
(10) Pub. No.: US 2003/0137000 A1
(43) Pub. Date: Jul. 24, 2003

(54) Flash memory with virtual ground scheme

(76) Inventors: Tso-Hung Fan, Taipei (TW); Tao-Cheng Lu, Kaohsiung (TW)

Correspondence Address: BIRCH STEWART KOLASCH & BIRCH, PO BOX 747, FALLS CHURCH, VA, 22040-0747, US

(21) Appl. No.: 10/290,306

(22) Filed: Nov. 8, 2002

(30) Foreign Application Priority Data
Jan. 23, 2002 (TW) 091101072

(51) Int. Cl. H01L 29/76; H01L 29/788

(52) U.S. Cl. 257/314; 257/316; 257/321

(57) ABSTRACT

A flash memory with virtual ground scheme. The memory includes a first type substrate, second type doped regions, a stacked gate structure, a first type ion-implanted region, and switches. The second type doped regions are formed in the first type substrate. The stacked gate structure is formed on the surface of the first type substrate and between the second type doped regions. The first type ion-implanted region is formed on only one side of the second type doped region and the first type substrate. The switches are coupled to the second type doped regions respectively for selective provision of a predetermined voltage value and a ground level to the second type doped regions.

### BACKGROUND OF THE INVENTION

1. Field of the Invention

The present invention relates in general to a flash memory. In particular, the present invention relates to a flash memory with virtual ground scheme.

2. Description of the Related Art

Computers, personal digital assistants, cellular telephones and other electronic systems and devices typically include processors and memories. The memory is used to store instructions (typically in the form of computer programs) to be executed and/or data to be operated on by the processors to achieve the functionality of the device. In some applications, the systems and devices may require that the instructions and/or data be retained in some form of a permanent/non-volatile storage medium so that the information is not lost when the device is turned off or power is removed. Exemplary applications include computer BIOS storage and diskless handheld computing devices such as personal digital assistants.

Flash memories are popular memory storage devices because their cost is decreased by decreasing the size of memory cells. The data line pitch of memory cell is decreased as the gate length to reduce the size of the memory. However, the decreasing of the floating gate will decrease the coupling ratio between the floating gate and the control gate. Thus, it is a challenge to decrease the size of the flash memory cell and maintain a high gate coupling ratio.

FIG. 1 shows a cross-section of a conventional stacked gate nonvolatile memory cell. In FIG. 1, numeral 1 represents a P-type silicon substrate. Numeral 2 represents a tunneling dielectric layer formed on the silicon substrate generally consisting of a SiO₂ layer, while SiON, Si₃N₄, HfO₂ or ZrO₂ can also be employed. Numeral 3 represents a floating gate (FG) formed on the tunneling dielectric layer generally consisting of polysilicon. Numeral 4 represents a dielectric layer formed on the floating gate generally consisting of SiO₂, ONO, SiON, Si₃N₄, HfO₂ or ZrO₂. Numeral 5 represents a control gate (CG) formed on the dielectric layer. A capping dielectric layer 6 may be formed on the upper portion of the control gate (CG) 5 according to the demand. Each sidewall of the stacked gate has a spacer 7 generally consisting of an oxide or nitride. One side of the stacked gate has an N-type doped source region 8 and the other side has an N-type doped drain region 9. The stacked gate nonvolatile cell can be erased by F-N tunneling effect through the source region 8, the drain region 9 or the silicon substrate 1 to release electrons trapped in the floating gate 3.

Flash memory with virtual ground scheme is provided to improve the integration of the flash memory array. FIG. 2 shows a circuit diagram of conventional flash memories with virtual ground scheme. The source/drain regions of adjacent cells use a single doped region. The bit line driver 20 selects a switch 22 to turn on and the power supply 24 provides high- or low-level signals to the memory cell to determine whether the doped region is source or drain. Thus, the number of source or drain regions and the area of the isolation structures are decreased to reduce the size of the memory array.

FIG. 3 shows a sectional view of conventional flash memories with virtual ground scheme. The P-type substrate 30 comprises N-type doped regions 31A, 31B, 31C, and 31D. The gates 320-322 are composed of the tunneling dielectric layer 32A, the floating gate 32B, the dielectric layer 32C and the control gate 32D, and is formed on the P-type substrate 30. The gate 320 is located between N-type doped regions 31A and 31B, the gate 321 is located between N-type doped regions 31B and 31C, and the gate 322 is located between N-type doped regions 31C and 31D.

In the prior art, there are symmetric pockets 34 formed by ion implantation near the junctions between both sides of the gates 320-322 and N-type doped regions to improve gate coupling ratio and increase threshold voltage. However, the symmetric pockets decrease the read current in read mode and influence data reading.

### SUMMARY OF THE INVENTION

The object of the present invention is to provide a flash memory with virtual ground scheme, in which the pockets are only formed near the junctions between one side of the gates and N-type doped regions.

The advantages of the asymmetric pockets are:

(1) Improved short channel effect, i.e. a decrease in leakage in small dimension flash cells.

(2) Increased read current compared to that in symmetric pockets.

(3) Increased gate coupling ratio compared to that without pockets.

To achieve the above-mentioned object, the present invention provides a flash memory with virtual ground scheme, including a first type substrate, second type doped regions, a stacked gate structure, a first type ion-implanted region, and switches. The second type doped regions are formed in the first type substrate. The stacked gate structure is formed on the surface of the first type substrate and between the second type doped regions. The first type ion-implanted region is formed only on one side of the second type doped region and the first type substrate. The switches are coupled to the second type doped regions respectively for selective provision of a predetermined voltage value and a ground level to the second type doped regions.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows a cross-section of a conventional stacked gate nonvolatile memory cell;

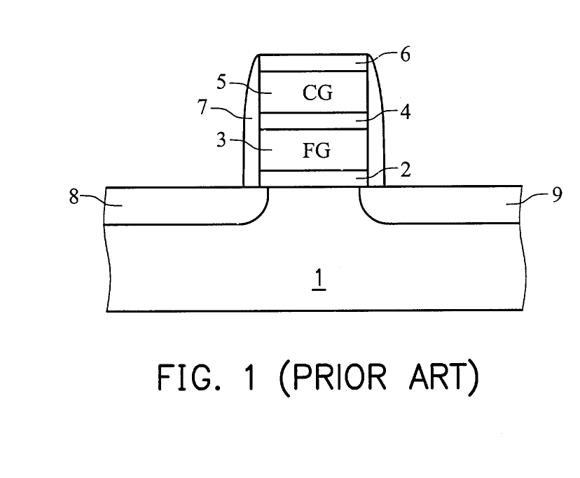

FIG. 2 shows a circuit diagram of a conventional flash memories with virtual ground scheme;

FIG. 3 shows a sectional view of conventional flash memories with virtual ground scheme; and

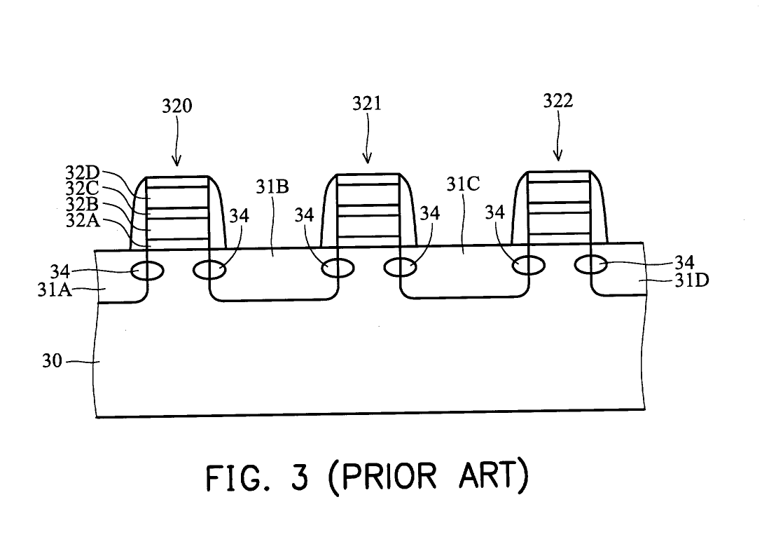

FIG. 4 shows a sectional view of the flash memories with virtual ground scheme according to the embodiment of the present invention.

### DETAILED DESCRIPTION OF THE INVENTION

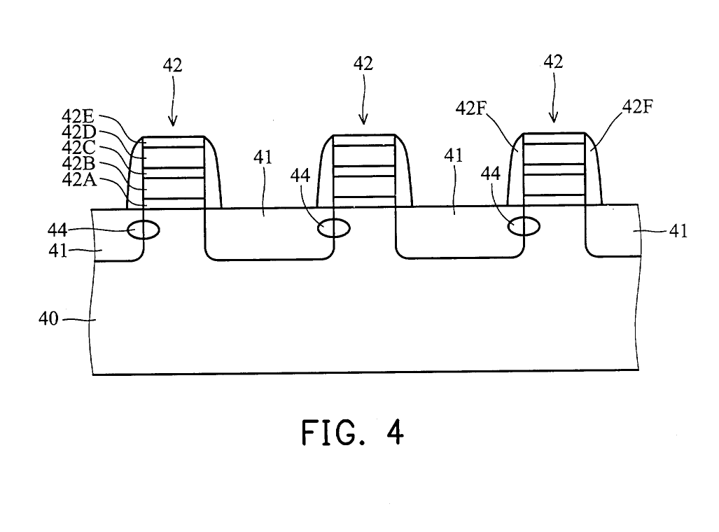

FIG. 4 shows the sectional view of the flash memories with virtual ground scheme according to the embodiment of the present invention. In FIG. 4, numeral 40 represents a P-type silicon substrate. Numeral 42A represents a tunneling dielectric layer formed on the silicon substrate 40 generally consisting of a SiO₂ layer, while SiON, Si₃N₄, HfO₂ or ZrO₂ can also be employed. Numeral 42B represents a floating gate (FG) formed on the tunneling dielectric layer generally consisting of polysilicon. Numeral 42C represents a dielectric layer formed on the floating gate generally consisting of SiO₂, ONO, SiON, Si₃N₄, HfO₂ or ZrO₂. Numeral 42D represents a control gate (CG) formed on the dielectric layer 42C. A capping dielectric layer 42E may be formed on the upper portion of the control gate (CG) 42D according to demand. Each sidewall of the stacked gate has a spacer 42F generally consisting of an oxide or nitride. Both sides of the stacked gate 42 comprise N-type doped regions 41. In erasing, the stacked gate nonvolatile cell can be erased by F-N tunneling to release electrons trapped in the floating gate 42B.

The junctions between the N-type doped region 41 and P-type substrate 40 comprise a P-type ion implanted region (pocket) 44. According to the present invention, the pocket 44 only exists on one side of the N-type doped region 41, different in that both sides of the N-type doped region of the prior art comprise pockets.

The pockets 44 formed by implanting BF₂ ions, Boron ions, or Indium ions. When using BF₂ ions, the implanting energy is between from 20 KeV to 200 KeV, the dose is between from 0.5e13m⁻⁻² to 1e14cm⁻², and the tilt angle is between from 10° to 45°. When using Boron ions, the implanting energy is between from 5 KeV to 50 KeV, the dose is between from 0.5e13m⁻² to 1e14cm⁻², and the tilt angle is between from 10° to 45°. When using Indium ions, the implanting energy is between from 20 KeV to 200 KeV, the dose is between from 0.5e13m⁻² to 1e14cm⁻², and the tilt angle is between from 10° to 45°.

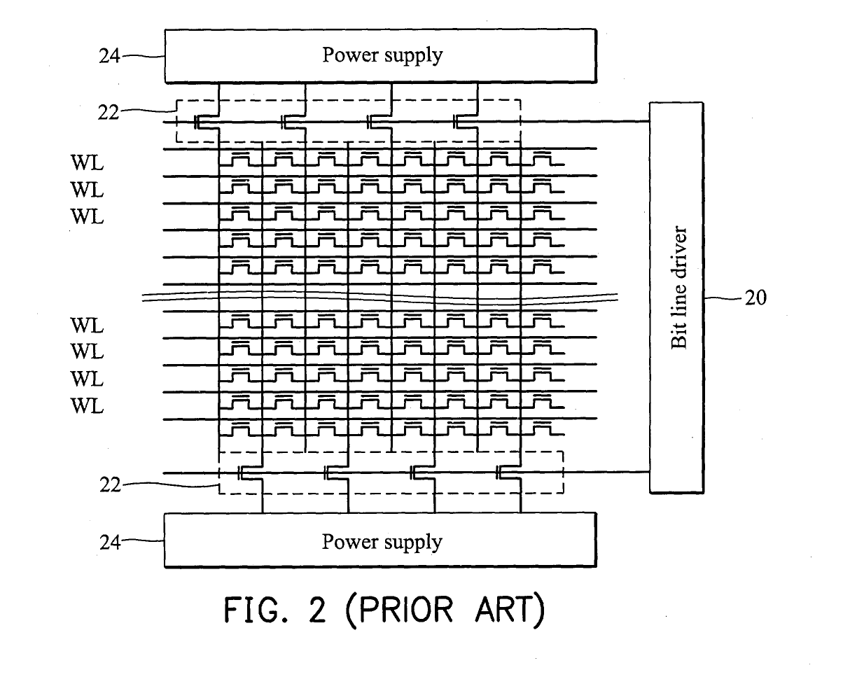

The N-type doped regions 41 are connected to the switches 22 as shown in FIG. 2. The bit line driver 20 selects a switch 22 to turn on and the power supply 24 provides high- or low-level signals to the memory cell to determine the doped region is source or drain. Thus, the numbers of the source or drain regions and the area of the isolation structures are decreased to reduce the size of the memory array.

Accordingly, the pockets are formed only at the junctions between one side of the gates and N-type doped regions of the flash memory with virtual ground scheme according to the present invention.

The advantages of the asymmetric pockets are:

(1) Improved short channel effect, i.e. a decrease in leakage in small dimension flash cells.

(2) Increased read current compared to that in symmetric pockets.

(3) Increased gate coupling ratio compared to that without pockets.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A flash memory with virtual ground scheme, comprising:
a first type substrate;
two second type doped regions formed in the first type substrate;
a stacked gate structure formed on the surface of the first type substrate and between the second type doped regions;
a first type ion-implanted region formed on only one side of the second type doped region and the first type substrate; and
two switches coupled to the second type doped regions respectively for selective provision of a predetermined voltage value and a ground level to the second type doped regions.

2. The flash memory with virtual ground scheme as claimed in claim 1, wherein the stacked gate structure comprises a tunneling dielectric layer, a floating gate, a first dielectric layer and a control gate.

3. The flash memory with virtual ground scheme as claimed in claim 1, wherein the first type ion-implanted region is doped BF₂ ions.

4. The flash memory with virtual ground scheme as claimed in claim 1, wherein the first type ion-implanted region is doped BF₂ ions with implanting energy between from 20 KeV to 200 KeV, dose between from 0.5e13m⁻² to 1e14cm⁻², and tilt angle between from 10° to 45°.

5. The flash memory with virtual ground scheme as claimed in claim 1, wherein the first type ion-implanted region is doped Boron ions.

6. The flash memory with virtual ground scheme as claimed in claim 1, wherein the first type ion-implanted region is doped Boron ions with implanting energy between from 5 KeV to 50 KeV, dose between from 0.5e13m⁻² to 1e14cm⁻², and tilt angle between from 10° to 45°.

7. The flash memory with virtual ground scheme as claimed in claim 1, wherein the first type ion-implanted region is doped Indium ions.

8. The flash memory with virtual ground scheme as claimed in claim 1, wherein the first type ion-implanted region is doped Indium ions with implanting energy between from 20 KeV to 200 KeV, dose between from 0.5e13m⁻² to 1e14cm⁻², and tilt angle between from 10° to 45°.

9. The flash memory with virtual ground scheme as claimed in claim 1, further comprising spacers formed on the sidewalls of the stacked gate structure.

10. The flash memory with virtual ground scheme as claimed in claim 9, wherein the spacers are oxide or nitride.

11. The flash memory with virtual ground scheme as claimed in claim 2, wherein the stacked gate structure further comprises a second dielectric layer.

12. The flash memory with virtual ground scheme as claimed in claim 2, wherein the first dielectric layer is oxide-nitride-oxide layer.

13. The flash memory with virtual ground scheme as claimed in claim 2, wherein the first dielectric layer is SiO₂, ONO, SiON, Si₃N₄, HfO₂ or ZrO₂ layer.

14. The flash memory with virtual ground scheme as claimed in claim 2, wherein the tunneling dielectric layer is Sio₂, ONO, SiON, Si₃N₄, HfO₂ or ZrO₂ layer.

15. The flash memory with virtual ground scheme as claimed in claim 2, wherein the floating gate is a polysilicon layer.

16. The flash memory with virtual ground scheme as claimed in claim 1, wherein the first type ion-implanted region is a pocket region.
